(19) United States
(12) Patent Application Publication
(10) Pub. No.: US 2025/0336435 A1
(43) Pub. Date: Oct. 30, 2025

(54) MEMORY DEVICE AND MANUFACTURING METHOD THEREOF, AND MEMORY SYSTEM

(71) Applicant: YANGTZE MEMORY TECHNOLOGIES CO., LTD., Wuhan (CN)

(72) Inventors: Danyang Li, Wuhan (CN); Xiang Fu, Wuhan (CN); Yu Wang, Wuhan (CN)

(21) Appl. No.: 18/781,547

(22) Filed: Jul. 23, 2024

(30) Foreign Application Priority Data
Apr. 28, 2024 (CN) 202410525618.3

(51) Int. Cl. G11C 11/408; G11C 11/4074; H01L 23/00; H01L 25/065; H01L 25/18; H10B 80/00

(52) U.S. Cl. CPC G11C 11/4085; G11C 11/4074; G11C 11/4087; H01L 24/08; H01L 25/0657; H01L 25/18; H10B 80/00; H01L 2224/08145; H01L 2924/1431; H01L 2924/1436

(57) ABSTRACT

According to one aspect of the present disclosure, a memory device is provided. The memory device may include a memory cell array. The memory device may include a plurality of word lines coupled with the memory cell array. The memory device may include a peripheral circuit coupled with the memory cell array through the plurality of word lines and comprising a drive circuit. The drive circuit may include a main driver and a plurality of word line drivers. Each of the word line drivers may be correspondingly coupled with each of the word lines. The main driver may be connected to n word line drivers, wherein n is an integer greater than 8.

### CROSS-REFERENCE TO RELATED APPLICATIONS

The present application claims the benefit of priority to Chinese Application No. 202410525618.3, filed on Apr. 28, 2024, which is hereby incorporated by reference in its entirety.

### TECHNICAL FIELD

Examples of the present disclosure relate to the technical field of semiconductors, and particularly to a memory device and a manufacturing method thereof, and a memory system.

### BACKGROUND

The semiconductor device such as a Dynamic Random Access Memory (DRAM) is one of the most important access components in an electronic system, and generally employs one transistor and one capacitor to constitute a 1T1C structure as a memory cell. Such 1T1C structure makes the dynamic random access memory have a high integration degree and a low cost, and have an irreplaceable position in the computer access device. With the rapid development of the semiconductor technology, the dynamic random access memory is rapidly developing towards high density and high quality.

### SUMMARY

According to one aspect of the present disclosure, a memory device is provided. The memory device may include a memory cell array. The memory device may include a plurality of word lines coupled with the memory cell array. The memory device may include a peripheral circuit coupled with the memory cell array through the plurality of word lines and comprising a drive circuit. The drive circuit may include a main driver and a plurality of word line drivers. Each of the word line drivers may be correspondingly coupled with each of the word lines. The main driver may be connected to n word line drivers, wherein n is an integer greater than 8.

In some implementations, the main driver may include a pre-charge circuit and an output circuit. In some implementations, a transistor size of a transistor in the output circuit may be greater than a transistor size of a transistor in the pre-charge circuit.

In some implementations, a ratio of a transistor size of a transistor in the output circuit to a transistor size of a transistor in the pre-charge circuit may range from 1.5 to 2.

In some implementations, the main driver may be connected to 16 word line drivers.

In some implementations, the peripheral circuit may further include a row decoder coupled to the drive circuit and configured to decode 9th-bit to 5th-bit row addresses in a row address signal of m bits to generate a main drive signal, and decode the row addresses of the lowest 4 bits in the row address signal of m bits to generate a word line drive signal, wherein m is an integer greater than 9. In some implementations, the drive circuit may be configured to drive a target word line based on the main drive signal and the word line drive signal.

In some implementations, the memory cell array my include a plurality of banks, each of the banks may include a plurality of groups, and each of the groups may include at least one block. In some implementations, an orthographic projection of the drive circuit may be located in an orthographic projection of the group.

In some implementations, the blocks in each of the groups may be arranged in an array along a word-line direction and a bit-line direction. In some implementations, an orthographic projection of the word line driver may be located between orthographic projections of the blocks adjacent to each other along the word-line direction.

In some implementations, the plurality of banks may be arranged in an array along a word-line direction and a bit-line direction. In some implementations, an orthographic projection of the row decoder may be located between orthographic projections of the banks adjacent to each other along the bit-line direction.

In some implementations, the drive circuit may further include a first power supply circuit configured to supply a charge voltage to the word line driver. In some implementations, an orthographic projection of the first power supply circuit may be located in the orthographic projection of the block.

In some implementations, the drive circuit may further include a second power supply circuit configured to supply a discharge voltage to the word line driver. In some implementations, an orthographic projection of the second power supply circuit may be located in the orthographic projection of the block.

In some implementations, the drive circuit may further include a drive circuit interconnection line configured to achieve the coupling between the first power supply circuit and the word line driver, and to achieve the coupling between the second power supply circuit and the word line driver. In some implementations, an orthographic projection of the drive circuit interconnection line may be located in the orthographic projection of the group, and the drive circuit interconnection line may extend along the word-line direction.

In some implementations, one of the word line drivers on two sides of the first one among the plurality of blocks may be coupled to an even number word line, and the other one is coupled to an odd number word line.

In some implementations, the memory cell array may include a plurality of memory cells, and each memory cell may include one vertical transistor and one capacitor.

In some implementations, the memory cell array and the peripheral circuit may be formed on different substrates, and the peripheral circuit and the memory cell array may be stacked in a vertical direction.

According to another aspect of the present disclosure, a memory system is provided. The memory system may include a memory device. The memory device may include a memory cell array. The memory device may include a plurality of word lines coupled with the memory cell array. The memory device may include a peripheral circuit coupled with the memory cell array through the plurality of word lines and comprising a drive circuit. The drive circuit may include a main driver and a plurality of word line drivers. Each of the word line drivers may be correspondingly coupled with each of the word lines. The main driver may be connected to n word line drivers, wherein n is an integer greater than 8. The memory system may include a memory controller coupled to the memory device and configured to control the memory device.

According to a further aspect of the present disclosure, a method of manufacturing a memory device is provided. The method may include forming a memory cell array and a plurality of word lines coupled with the memory cell array. The method may include forming a peripheral circuit. The forming a peripheral circuit may include forming a plurality of drive circuits. The drive circuit may include a main driver and a plurality of word line drivers. Each of the word line drivers may be correspondingly coupled with each of the word lines. The main driver may be connected to n word line drivers. n may be an integer greater than 8.

In some implementations, the forming the plurality of drive circuits may include forming a pre-charge circuit and an output circuit. In some implementations, a transistor size of a transistor in the output circuit may be greater than a transistor size of a transistor in the pre-charge circuit.

In some implementations, a ratio of a transistor size of a transistor in the output circuit to a transistor size of a transistor in the pre-charge circuit ranges from 1.5 to 2.

In some implementations, the main driver may be connected to 16 word line drivers.

In some implementations, the forming the peripheral circuit may further include forming a row decoder. In some implementations, the row decoder may be coupled to the drive circuit and configured to decode 9th-bit to 5th-bit row addresses in a row address signal of m bits to generate a main drive signal, and decode the row addresses of the lowest 4 bits in the row address signal of m bits to generate a word line drive signal, wherein m is an integer greater than 9. In some implementations, the word line driver may be configured to drive a target word line based on the main drive signal and the word line drive signal.

In some implementations, the forming the memory cell array may include forming the memory cell array including a plurality of banks. In some implementations, each of the banks may include a plurality of groups, and each of the groups may include at least one block. In some implementations, an orthographic projection of the drive circuit may be located in an orthographic projection of the group.

In some implementations, the blocks in the group may be arranged in an array along a word-line direction and a bit-line direction. In some implementations, the forming the plurality of drive circuits may include forming the plurality of word line drivers. In some implementations, an orthographic projection of the word line driver may be located between orthographic projections of the blocks adjacent to each other along the word-line direction.

In some implementations, the plurality of banks may be arranged in an array along a word-line direction and a bit-line direction. In some implementations, the forming the row decoder may include forming the row decoder whose orthographic projection is located between orthographic projections of the banks adjacent to each other along the bit-line direction.

In some implementations, the forming the peripheral circuit further may include forming a first power supply circuit. In some implementations, the first power supply circuit may be configured to supply a charge voltage to the word line driver. In some implementations, an orthographic projection of the first power supply circuit may be located in the orthographic projection of the block.

In some implementations, the forming the peripheral circuit may further include forming a second power supply circuit. In some implementations, the second power supply circuit may be configured to supply a discharge voltage to the word line driver. In some implementations, an orthographic projection of the second power supply circuit may be located in the orthographic projection of the block.

In some implementations, the forming the peripheral circuit may further include forming a drive circuit interconnection line. In some implementations, the drive circuit interconnection line may be configured to achieve the coupling between the first power supply circuit and the word line driver, and to achieve the coupling between the second power supply circuit and the word line driver. In some implementations, an orthographic projection of the drive circuit interconnection line may be located in the orthographic projection of the group, and the drive circuit interconnection line may extend along the word-line direction.

In some implementations, one of the word line drivers on two sides of the first one among the plurality of blocks may be coupled to an even number word line, and the other one is coupled to an odd number word line.

In some implementations, the forming the memory cell array may include forming a plurality of memory cells. In some implementations, each memory cell may include one vertical transistor and one capacitor.

In some implementations, the forming the memory cell array may include forming the memory cell array on a first substrate. In some implementations, the forming the peripheral circuit may include forming the peripheral circuit on a second substrate. In some implementations, the method may further include bonding the memory cell array and the peripheral circuit.

Examples of the present disclosure provide a memory device and a manufacturing method thereof, and a memory system. The memory device includes: a memory cell array; a plurality of word lines coupled with the memory cell array; and a peripheral circuit coupled with the memory cell array through the plurality of word lines and including a drive circuit, wherein the drive circuit includes a main driver and a plurality of word line drivers; each of the word line drivers is correspondingly coupled with each of the word lines; and the main driver is connected to n word line drivers, wherein n is an integer greater than 8. In the examples of the present disclosure, each main driver is connected to more than 8 word line drivers, such that one main driver may drive more than 8 word lines (local word lines), thereby greatly improving an integration level of the memory device.

### BRIEF DESCRIPTION OF THE DRAWINGS

FIG. 1 is a schematic diagram of an example system having a memory system according to an example of the present disclosure;

FIG. 2 is a schematic diagram of an example computer system having a memory system according to an example of the present disclosure;

FIG. 3 is a schematic diagram of a memory device according to an example of the present disclosure;

FIG. 4 is a schematic distribution diagram of a memory cell array and a peripheral circuit in an example memory device according to an example of the present disclosure;

FIG. 5 is a schematic distribution top view I of a memory cell array and a peripheral circuit in an example memory device according to an example of the present disclosure;

FIG. 6 is a schematic distribution top view II of a memory cell array and a peripheral circuit in an example memory device according to an example of the present disclosure;

FIG. 7 is a schematic diagram of a drive circuit in an example peripheral circuit according to an example of the present disclosure;

FIG. 8 is a schematic diagram of a word line driver in an example drive circuit according to an example of the present disclosure;

FIG. 9 is a schematic diagram of a main driver in an example drive circuit according to an example of the present disclosure;

FIG. 10 is a schematic diagram of decoding an example row address signal according to an example of the present disclosure;

FIG. 11A is a partial schematic diagram of an example memory device according to an example of the present disclosure;

FIG. 11B is an enlarged schematic diagram of an example first group according to an example of the present disclosure;

FIG. 11C is an enlarged schematic diagram of an example second group according to an example of the present disclosure;

FIG. 11D is an enlarged schematic diagram of an example third group according to an example of the present disclosure; and

FIG. 12 is a flow diagram of a manufacturing method of a memory device provided by an example of the present application.

### DETAILED DESCRIPTION

The technical solutions in implementations of the present disclosure will be described below clearly and completely in conjunction with the implementations and the drawings of the present disclosure. Apparently, the implementations described are only part, but not all, of the implementations of the present disclosure. All other implementations obtained by those of ordinary skills in the art based on the implementations in the present disclosure without creative work shall fall within the scope of protection of the present disclosure.

In the description below, many specific details are presented to provide a more thorough understanding of the present disclosure. However, it is apparent to those skilled in the art that the present disclosure may be implemented without one or more of these details. In other examples, in order to avoid confusion with the present disclosure, some technical features well-known in the field are not described. That is, all the features of the actual examples are not described here, and well-known functions and structures are not described in detail.

In the drawings, the sizes of a layer, a region, and an element and their relative sizes may be exaggerated for clarity. Like reference numerals denote like elements throughout the specification.

It is to be understood that when an element or a layer is referred to as being “on”, “adjacent to”, “connected to”, or “coupled to” other elements or layers, it may be directly on, adjacent to, connected to, or coupled to the other elements or layers, or intervening elements or layers may be present. In contrast, when an element is referred to as being “directly on”, “immediately adjacent to”, “directly connected to”, or “directly coupled to” other elements or layers, no intervening elements or layers are present. It is to be understood that, although terms first, second, third and the like may be used to describe various elements, components, regions, layers and/or sections, these elements, components, regions, layers and/or sections should not be limited by these terms. These terms are only used to distinguish one element, component, region, layer or portion from another element, component, region, layer or portion. Thus, a first element, component, region, layer or portion discussed below may be represented as a second element, component, region, layer or portion, without departing from the teachings of the present disclosure. However, when the second element, component, region, layer or portion is discussed, it does not mean that the first element, component, region, layer or portion is necessarily present in the present disclosure.

The spatially relative terms, such as “beneath”, “below”, “lower”, “under”, “above”, “upper”, and the like, may be used herein for ease of description to describe one element or feature's relationship to other elements or features as illustrated in the figures. It is to be understood that the spatially relative terms are intended to further encompass different orientations of a device in use or operation in addition to the orientation depicted in the figures. For example, if the device in the drawings is turned over, then the elements or the features described as “below” or “under” or “beneath” other elements would be oriented “on” the other elements or features. Thus, the example terms, “below” and “beneath”, may comprise both upper and lower orientations. The device may be orientated otherwise (rotated by 90 degrees or other orientations), and the spatially descriptive terms used herein are interpreted accordingly.

The terms used herein are only intended to describe the examples, and are not used as limitations of the present disclosure. As used herein, unless otherwise indicated expressly in the context, “a”, “an” and “the” in a singular form are also intended to comprise a plural form. It should also be understood that terms “consist of” and/or “comprise”, when used in this specification, determine the presence of the described features, integers, steps, operations, elements and/or components, but do not preclude the presence or addition of one or more of other features, integers, steps, operations, elements, components, and/or groups. As used herein, the term “and/or” comprises any or all combinations of the listed relevant items.

In order to understand the present disclosure thoroughly, detailed steps and detailed structures will be proposed in the following description to set forth the technical solutions of the present disclosure. The detailed descriptions of the preferred examples of the present disclosure are as follows. However, the present disclosure may also have other implementations in addition to these detailed descriptions.

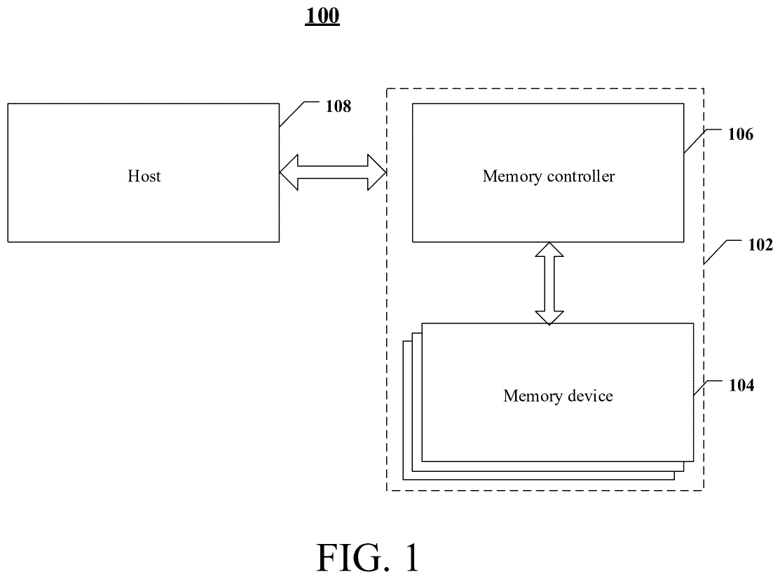

FIG. 1 shows a block diagram of an example system 100 having a memory device according to some aspect of the present disclosure. The system 100 may include a mobile phone, a desktop computer, a laptop computer, a tablet computer, a vehicle computer, a gaming console, a printer, a positioning apparatus, a wearable electronic apparatus, a smart sensor, a Virtual Reality (VR) apparatus, an Augmented Reality (AR) apparatus, or any other suitable electronic apparatus having a storage therein. As shown in FIG. 1, the system 100 may include a host 108 and a memory system 102, and the memory system 102 is provided with one or more memory devices 104 and a memory controller 106. The host 108 may be a processor of an electronic apparatus (e.g., a central processing unit (CPU) or a graphic processing unit (GPU)). The host 108 may be configured to send or receive data to or from the memory device 104. The memory controller 106 is coupled to the memory device 104 and the host 108, and is configured to control the memory device 104. The memory controller 106 may manage data stored in the memory device 104, and communicate with the host 108.

The memory controller 106 may be configured to control operations of the memory device 104, such as read, erase, write, and refresh operations. In some implementations, the memory controller 106 is further configured to process error correction codes (ECC) with respect to the data read from or written to the memory device 104. The memory controller 106 may further perform any other suitable functions, for example, formatting the memory device 104. The memory controller 106 may communicate with an external apparatus (e.g., the host 108) according to a specific communication protocol.

In some examples, one or more memory devices 104 and the memory controller 106 may all be integrated into various types of storage apparatuses. For example, the plurality of memory devices 104 may be integrated into a memory module; and the memory controller 106 may be integrated into a north bridge of a mainboard or directly integrated in a CPU. That is, the memory system 102 may be implemented and packaged into different types of end electronic products.

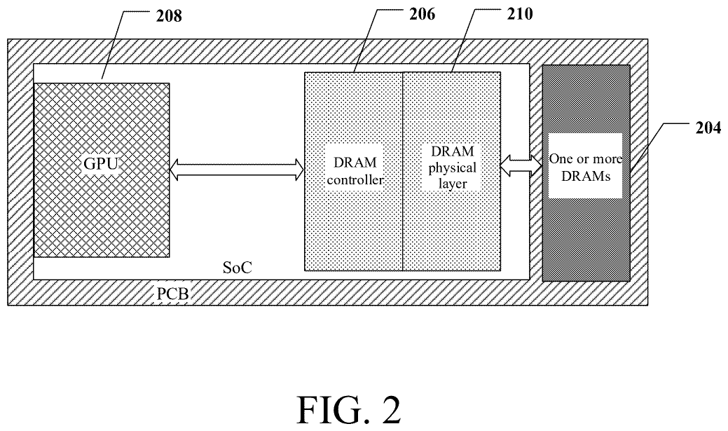

In one system example shown in FIG. 2, the system includes a System-on-Chip (SoC) and one or more memory devices; the memory device includes a DRAM 204; and the SoC includes a graphic processing unit (GPU) 208, a DRAM controller 206, and a DRAM physical layer 210, where the DRAM controller 206 is responsible for scheduling of read and write instructions and timing control of the DRAM 204; the DRAM physical layer 210 is responsible for completing the encoding of scheduled instructions according to requirements of the DRAM 204, sending respective write data to the DRAM 204, and receiving data read from the DRAM 204.

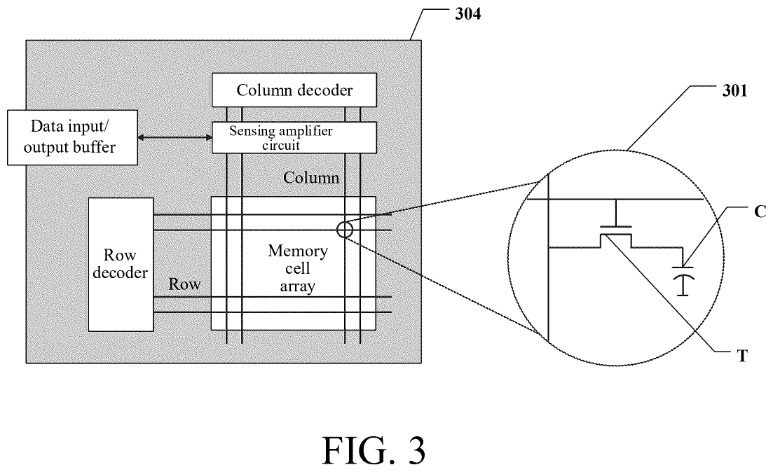

FIG. 3 is a schematic diagram of a DRAM of an example memory device according to an example of the present disclosure; and a circuit of a memory cell in the DRAM is shown on the right side of FIG. 3. Each DRAM die 304 includes a memory cell array, the memory cell array includes a plurality of memory cells 301 arranged in an array, each memory cell 301 includes one transistor T and one Capacitor C, and a main working principle of the memory cell is to utilize the amount of charge stored in the capacitor to represent whether a binary bit is 1 or 0. The memory cells are arranged in an array, which may be regarded as a typical grid structure. The memory array employs rows and columns to designate addresses. By designating intersections of the rows and the columns (by designating row addresses and column addresses of the DRAM), the memory controller may independently access the respective memory cell in a DRAM die, and perform the read or write operation on data stored therein.

In some examples, the memory device includes a memory cell array and a peripheral circuit, where the memory cell array includes a plurality of banks, each of the banks is divided into a plurality of groups, each of the groups may include a plurality of blocks, each of the blocks includes a plurality of memory cell rows and a plurality of memory cell columns, each memory cell row is coupled with one corresponding word line, and each memory cell column is coupled with one corresponding bit line. The peripheral circuit includes a series of Complementary Metal-Oxide-Semiconductor (CMOS) control circuits. The series of CMOS control circuits may include: a control circuit corresponding to each block, such as a Sensing Amplifier (SA) circuit, a Word-Line Driver (WLD) circuit, etc.; a control circuit corresponding to each bank, such as a row decoder, a column decode, etc.; and a control circuit corresponding to all the banks, such as a command buffer, a command decoder, an address buffer, a data buffer, a mode register, etc.

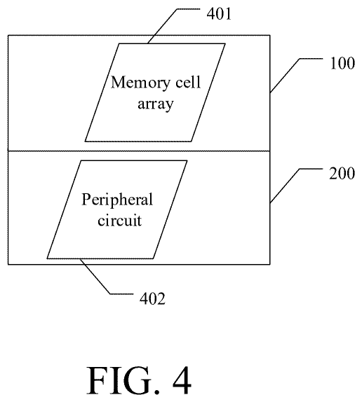

The memory device is described below in detail with reference to FIGS. 4 to 6. Before the memory device shown in FIGS. 4 to 6 is introduced, various directions that may be used in descriptions below are defined first. A stacking direction of the memory cell array and the peripheral circuit is defined as a vertical direction (e.g., a Z-axis direction). A word-line direction (e.g., a X-axis direction) and a bit-line direction (e.g., a Y-axis direction) intersecting with each other are defined in a plane perpendicular to the Z-axis direction. In some examples, the X-axis direction, the Y-axis direction, and the Z-axis direction may be perpendicular to each other.

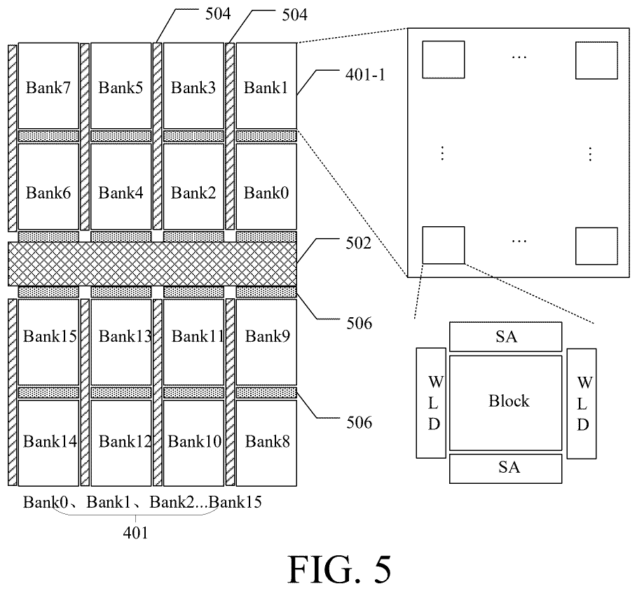

In a practical application process, a layout is provided between the memory cell array and the peripheral circuit. In some examples, the memory cell array and the peripheral circuit are arranged in juxtaposition on different substrates. In an example, FIG. 4 shows a schematic distribution diagram of a memory cell array and a peripheral circuit in an example memory device; and FIG. 5 shows a schematic distribution top view I of a memory cell array and a peripheral circuit in an example memory device. As shown in FIG. 4, the memory cell array 401 and the peripheral circuit 402 are stacked in the vertical direction. In an example, at least one side of each block is provided with a control circuit corresponding to the block, at least one side of each bank is provided with a control circuit corresponding to the bank, one bank row is formed by every k banks among M banks, the M banks form M/K bank rows, and a peripheral circuit corresponding to all the banks is disposed between two bank rows in the middle. It is to be noted that, M, N, and K here are all positive integers, and M is an integer multiple of K.

In some examples, the memory cell array 401 and the peripheral circuit 402 are arranged on two substrates. As shown in FIG. 4, the example memory device may include a first substrate 100 at least including the memory cell array 401, and a second substrate 200 at least including the peripheral circuit 402. The first substrate 100 and the second substrate 200 are stacked and connected in a bonding manner.

Herein, the first substrate 100 may include, but is not limited to, a silicon substrate. The first substrate 100 may at least include the memory cell array 401. In the following, the first substrate 100 may further include a dummy memory cell array. The memory cell array 401 may include the plurality of banks arranged in an array, each of the banks includes the plurality of blocks arranged in an array, each of the blocks includes a plurality of memory cell rows and a plurality of memory cell columns, each memory cell row and each memory cell column respectively include the plurality of memory cells, and the memory cell array 401 may further include a plurality of word lines and a plurality of bit lines, each memory cell row is coupled with one corresponding word line, and each memory cell column is coupled with one corresponding bit line.

Herein, the second substrate 200 and the first substrate are different substrates, and the second substrate includes, but is not limited to, a silicon substrate. In the following, the second substrate 200 includes the peripheral circuit 402; and the peripheral circuit 402 may include at least one of the control circuit corresponding to the block or the control circuit corresponding to the bank. Herein, the peripheral circuit 402 further includes the control circuit corresponding to all the banks, such as a command buffer, a command decoder, an address buffer, a data buffer, a mode register, etc.

In some examples, the memory device shown in FIG. 4 may further include, e.g., a bonding interface located between the first substrate and the second substrate, a first interconnect layer located between the first substrate and the bonding interface, and a second interconnect layer located between the second substrate and the bonding interface. The first substrate and the second substrate may be connected through the first interconnect layer, the bonding interface, and the second interconnect layer.

Herein, the memory device may further include the bonding interface, the first interconnect layer, and the second interconnect layer. The first interconnect layer and the second interconnect layer may each include a plurality of bonding contacts and dielectrics electrically isolating the bonding contacts. In some examples, the bonding contact may include a conductive material, including, but not limited to, tungsten (W), cobalt (Co), copper (Cu), aluminum (Al), silicides, or any combination thereof; and the dielectric may include, but not limited to, silicon oxide, silicon nitride, and silicon oxynitride, low-k (a dielectric constant being less than 3.9) dielectrics, or any combination thereof. In some examples, the first interconnect layer is formed on the first substrate; the second interconnect layer is formed on the second substrate; then the memory array included in the first substrate and the peripheral circuit included in the second substrate are bonded on the bonding interface; and the bonding contacts and the surrounding dielectrics may be connected by employing hybrid bonding. That is, in some examples, the bonding interface is vertically formed between the first interconnect layer and the second interconnect layer. In some examples, the memory cell array in the first substrate and the peripheral circuit in the second substrate are bonded on the bonding interface through the bonding contacts included in the first interconnect layer and the bonding contacts included in the second interconnect layer, so as to achieve a connection between the memory cell array and the peripheral circuit.

In an example, as shown in FIG. 5, the memory cell array 401 includes 16 banks 401-1, each of the banks includes the plurality of blocks, with SAs and WLDs corresponding to the block being oppositely arranged at the periphery of each block. A column decoder 504 and a row decoder 506 corresponding to the bank are arranged on two sides of each bank. One bank row is formed by every 4 banks and thus 4 bank rows are formed by the 16 banks, with a control circuit 502 arranged between two bank rows in the middle. It is to be noted that the number of banks in FIG. 5 is provided by way of example only, and is not used to limit the number of banks in the memory device in the present disclosure.

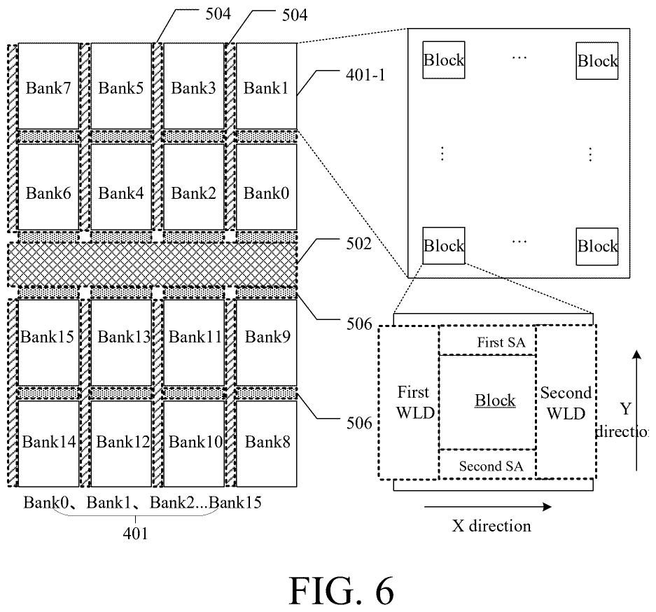

In an example, FIG. 6 shows a schematic distribution top view II of the memory cell array and the peripheral circuit in the memory device. It is to be noted that, the first substrate 100 in FIG. 6 is located above the second substrate 200, a structure corresponding to a solid line in FIG. 6 is a structure located in the first substrate 100, a structure corresponding to a dashed line is a structure located in the second substrate 200, and for ease of understanding, a perspective view of the structure in the second substrate 200 is provided.

In an example, as shown in FIG. 6, the memory cell array 401 includes 16 banks 401-1, each of the banks includes the plurality of blocks, with a first SA and a second SA that are oppositely arranged along a first direction and correspond to the block and a first WLD and a second WLD that are oppositely arranged along a second direction being arranged right under each of the blocks. A column decoder 504 and a row decoder 506 corresponding to the bank are arranged below the two sides of each of the banks. One bank row is formed by every 4 banks, and thus 4 bank rows are formed by the 16 banks, with a control circuit 502 arranged between two bank rows in the middle.

It is to be noted that the number of banks in FIG. 6 is for example only, and is not used to limit the number of banks in the memory device in the present disclosure.

It is to be noted that, a relationship between a size of one block and sizes of surrounding SAs and word line drivers shown in FIG. 6 is for example only, and is not used to limit a relationship between the size of one block in the memory device in the present disclosure and the sizes of the surrounding SAs and word line drivers.

It is to be noted that, the above is only two example layout manners of the memory cell array and the peripheral circuit, but there may also be other layouts actually, and more layout manners are not described herein again.

In order to reduce an area occupied by the peripheral circuit to reduce a size of the memory device, examples of the present disclosure further provide another memory device. The memory device may include a memory cell array; a plurality of word lines coupled with the memory cell array; and a peripheral circuit coupled with the memory cell array through the plurality of word lines and including a drive circuit. The drive circuit includes a main driver and a plurality of word line drivers. Each of the word line drivers is correspondingly coupled with each of the word lines. The main driver is connected to n word line drivers, where n is an integer greater than 8.

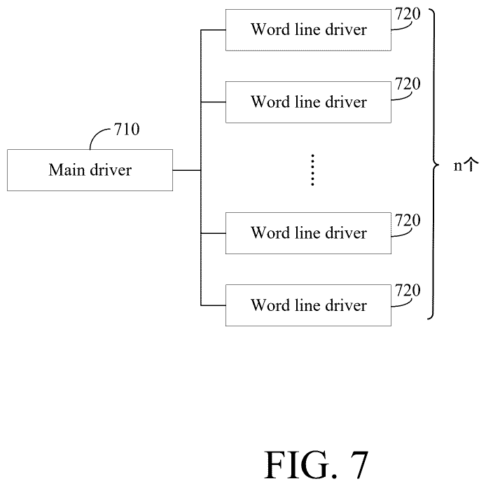

FIG. 7 is a schematic diagram of a drive circuit in an example peripheral circuit according to an example of the present disclosure. Referring to FIG. 7, the drive circuit includes a main driver 710 and a plurality of word line drivers 720; each of the word line drivers 720 is correspondingly coupled with each of the word lines; and the main driver 710 is connected to n word line drivers 720.

In some examples, the main driver 710 is connected to 16 word line drivers 720.

Each main word line (MWL) (also referred to as a “global word line”) driven by the main driver 710 may be coupled to 16 word line drivers 720, and each word line driver 720 may be coupled to the corresponding word line WL (e.g., a local word line (LWL)) in the memory cell array. The word line driver 720 and the main driver 710 are used in a combined manner to control a voltage on the corresponding word line WL. A word line extending from the main driver 710 to the word line driver 720 may be referred to as the main word line. A word line extending from the word line driver 720 to the memory cell array may be referred to as the local word line.

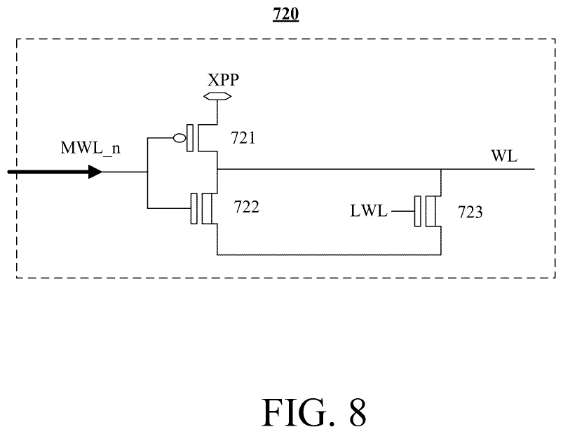

In some examples, the word line driver 720 may include a word line drive transistor configured to transfer a voltage from the main word line to the word line WL. FIG. 8 is a schematic diagram of a word line driver in an example drive circuit according to an example of the present disclosure. Referring to FIG. 8, the word line driver 720 includes a first transistor 721, a second transistor 722, and a third transistor 723. The first transistor 721 is a PMOS transistor, and the second transistor 722 and the third transistor 723 are NMOS transistors. In some implementations, a node XPP is connected with a first power supply circuit, a node LWL is connected with a second power supply circuit, and a node MWL_n is connected with the main driver 710. When an enable signal provided by the first power supply circuit is in a high level state (VPP), an enable signal provided by the second power supply circuit is in a low level state (VSS), and an enable signal provided by the main driver 710 is in the low level state (VSS), the voltage on the word line WL is pulled up to an operation voltage Vpp.

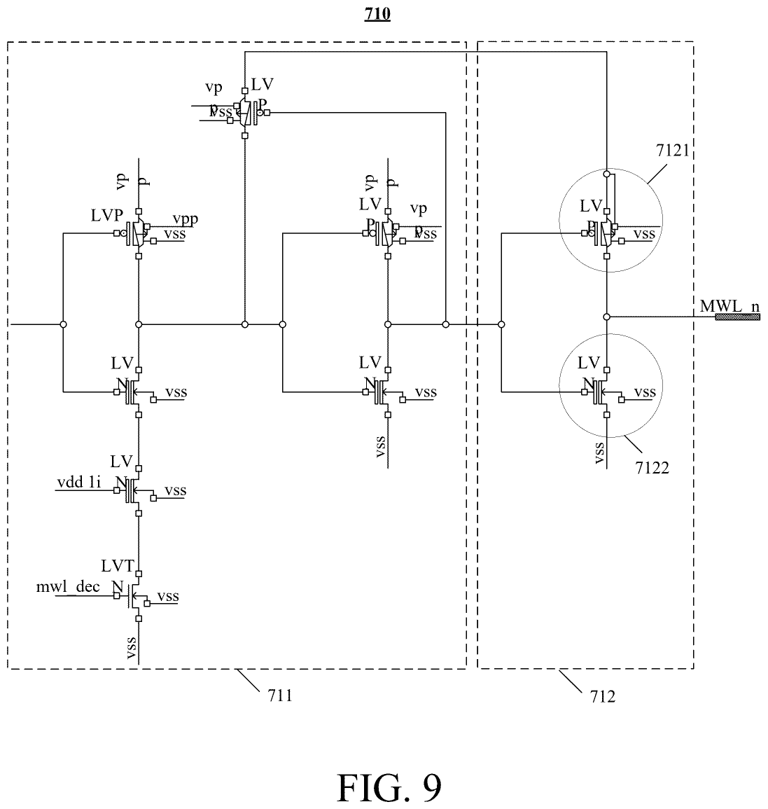

In some examples, FIG. 9 is a schematic diagram of a main driver in an example drive circuit according to an example of the present disclosure. Referring to FIG. 9, the main driver 710 includes a pre-charge circuit 711 and an output circuit 712; a transistor size of a transistor in the output circuit 712 is greater than a transistor size of a transistor in the pre-charge circuit 711. In some implementations, a transistor size of an NMOS transistor in the output circuit 712 is greater than a transistor size of an NMOS transistor in the pre-charge circuit 711.

In some implementations, the output circuit 712 includes a pull-up transistor 7121 and a pull-down transistor 7122; and a transistor size of the pull-down transistor 7122 in the output circuit 712 is greater than a transistor size of the NMOS transistor in the pre-charge circuit 711. In some other implementations, the transistor size of the pull-down transistor 7122 is greater than a transistor size of the pull-up transistor 7121. The pull-up transistor 7121 is a PMOS transistor, and the pull-down transistor 7122 is an NMOS transistor. A drive current output by the main driver 710 is determined by a pull-down current flowing through the pull-down transistor 7122.

In some implementations, the transistor size refers to a ratio of a channel width to a channel length. In some other examples, the transistor size is adjusted by maintaining the channel length unchanged and adjusting the channel width.

In some examples, a ratio of a transistor size of a transistor in the output circuit to a transistor size of a transistor in the pre-charge circuit ranges from 1.5 to 2.

In some implementations, a ratio of the transistor size of the pull-down transistor 7122 to the transistor size of the pull-up transistor 7121 ranges from 1.5 to 2.

Compared to the main driver being connected to 8 word line drivers, the main driver connected to 16 word line drivers has a larger driving pressure, such that the main driver uses a larger drive current to accelerate a driving speed thereof. The current of the transistor is proportional to the transistor size. In some implementations, the transistor size refers to the ratio of the channel width to the channel length. Based on the adjustment of the size of the pull-up transistor, the pull-down current of the pull-down transistor may be increased to 1.5 to 2 times. In some other examples, the transistor size is adjusted by maintaining the channel length unchanged and adjusting the channel width. In the examples of the present disclosure, reduction in the driving speed caused by the connection of more word line drivers (more than 8 word line drivers) can be greatly made up only by increasing a transistor width of one transistor (the pull-down transistor in the output circuit) in the main driver.

In some examples, the memory cell array includes the plurality of banks, each of the banks includes the plurality of groups, and each of the groups includes at least one block.

In some examples, the peripheral circuit further includes: a row decoder coupled to the drive circuit and configured to: decode 9th-bit to 5th-bit row addresses in a row address signal of m bits to generate a main drive signal, and decode the row addresses of the lowest 4 bits in the row address signal of m bits to generate a word line drive signal, where m is an integer greater than 9; and the drive circuit is configured to drive a target word line based on the main drive signal and the word line drive signal.

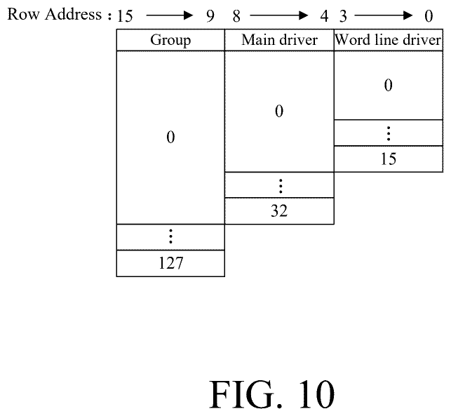

In some implementations, FIG. 10 is a schematic diagram of decoding an example row address signal according to an example of the present disclosure. Referring to FIG. 10, the row decoder receives a row address signal of 16 bits, Row Address <15:0>; and the row decoder decodes the 16th-bit to 10th-bit row addresses Row Address<15:9> in the row address signal of 16 bits to generate a group signal, decodes 9th-bit to 5th-bit row addresses Row Address<8:4> in the row address signal of 16 bits to generate the main drive signal, and decodes the row addresses Row Address<3:0> of the lowest 4 bits in the row address signal of 16 bits to generate the word line drive signal. The group signal is configured to activate a target group; the main drive signal is configured to activate a target main word line; and the word line drive signal is configured to activate a target word line. In some implementations, each bank includes 128 groups, and each group includes 32 main word lines and 512 word lines WLs. The drive circuit may activate, based on the main drive signal, one target main word line via one of 32 main drivers connected with the target group, and activate, based on the word line drive signal, one target word line WL via one of 16 word line drivers connected with the main driver connected with the target main word line.

In some examples, the plurality of banks are arranged in an array along a word-line direction and a bit-line direction; and an orthographic projection of the row decoder is located between orthographic projections of the banks adjacent to each other along the bit-line direction. Memory cells included by the bank described here are memory cells that function to perform actual storage functions, e.g., the bank does not include dummy cells that do not function to perform the actual storage functions.

It is to be noted that, the orthographic projection is a projection of a device structure on a reference plane along the vertical direction, and the reference plane is a lower surface of the memory device or a plane in which the lower surface is located. Herein, the reference plane is parallel to the bonding interface of the memory cell array and the peripheral circuit.

Continuously referring to FIGS. 5 to 6, the plurality of banks are arranged in an array along a word-line direction (X-axis direction) and a bit-line direction (Y-axis direction). In the examples of the present disclosure, the memory cell array and the peripheral circuit are formed on different substrates. The memory cell array is formed on the first substrate, and in a plan view of the first substrate, a region on the first substrate that is occupied by each bank is referred to as a first region. The peripheral circuit is formed on the second substrate, and in a plan view of the second substrate, a region on the second substrate that is occupied by each row decoder is referred to as a second region. After the memory cell array and the peripheral circuit are bonded, an orthographic projection of the second region is located between orthographic projections of the first regions adjacent to each other along the Y-axis direction. In some implementations, the main driver may be arranged in the second region. In other words, an orthographic projection of the main driver is located between the orthographic projections of the banks adjacent to each other along the bit-line direction.

In some examples, an orthographic projection of the drive circuit is located in an orthographic projection of the group.

Continuously referring to FIGS. 5 to 6, the plurality of blocks are arranged in an array along the word-line direction (X-axis direction) and the bit-line direction (Y-axis direction). In some implementations, a region on the first substrate that is occupied by each group is referred to as a third region. A region on the second substrate that is occupied by each drive circuit is referred to as a fourth region. After the memory cell array and the peripheral circuit are bonded, the third region and the fourth region overlap in the vertical direction, in other words, an orthographic projection of the third region overlaps with an orthographic projection of the fourth region, and the orthographic projection of the fourth region is located in the orthographic projection of the third region.

In some examples, the blocks in each of the groups are arranged in an array along the word-line direction and the bit-line direction; and an orthographic projection of the word line driver is located between orthographic projections of the blocks adjacent to each other along the word-line direction. Memory cells included in the block described here are memory cells that function to perform actual storage functions, e.g., the block does not include dummy cells that do not function to perform the actual storage functions.

In some implementations, a region on the first substrate that is occupied by each block is referred to as the third region. The region on the second substrate that is occupied by each drive circuit is referred to as the fourth region. The fourth region further includes a first sub-region in which the word line driver is disposed. After the memory cell array and the peripheral circuit are bonded, an orthographic projection of the first sub-region is located between orthographic projections of the third regions adjacent to each other along the X-axis direction.

In some examples, one of the word line drivers on two sides of the first one among the plurality of blocks in an orthographic projection direction is coupled to an even number word line, and the other one is coupled to an odd number word line.

Continuously referring to FIG. 6, the word line driver may further include an even number word line driver (first WLD) and an odd number word line driver (second WLD). In some implementations, the even number word line driver may be configured to control the even number word line of the block, and the odd number word line driver may be configured to control the odd number word line of the block. In some implementations, the even number word line driver may be shared by a first block and a second block arranged adjacent to a left side of the first block; and the odd number word line driver may be shared by the first block and another third block arranged adjacent to a right side of the first block. In some implementations, the even number word line driver may be configured to control the even number word line of the first block and the even number word line of the adjacent second block, and the odd number word line driver may be configured to control the odd number word line of the first block and the odd number word line of another adjacent third block.

In some implementations, the even number word lines (e.g., WL0, WL2, WL4, WL6, WL8, WL10, WL12, and WL14) may be connected to the even number word line driver; and the odd number word lines (e.g., WL1, WL3, WL5, WL7, WL9, WL11, WL13, and WL15) may be connected to the odd number word line driver.

In some examples, the drive circuit further includes: a first power supply circuit configured to supply a charge voltage to the plurality of word line drivers; and an orthographic projection of the first power supply circuit is located in the orthographic projection of the block.

In some examples, the drive circuit further includes: a second power supply circuit configured to supply a discharge voltage to the plurality of word line drivers; and an orthographic projection of the second power supply circuit is located in the orthographic projection of the block.

In some implementations, the first power supply circuit is configured to supply the charge voltage to the word line driver of the block in the corresponding groups. In some implementations, the second power supply circuit is configured to supply the discharge voltage to the word line driver of the block in the corresponding groups.

In some implementations, the fourth region may include a second sub-region in which the first power supply circuit is disposed, and a third sub-region in which the second power supply circuit is disposed. In some implementations, the second sub-region and the third region are at least partially overlapped in the vertical direction. In some other implementations, an orthographic projection of the second sub-region is located in the orthographic projection of the third region. In some implementations, the third sub-region and the third region are at least partially overlapped in the vertical direction. In some other implementations, an orthographic projection of the third sub-region is located in the orthographic projection of the third region.

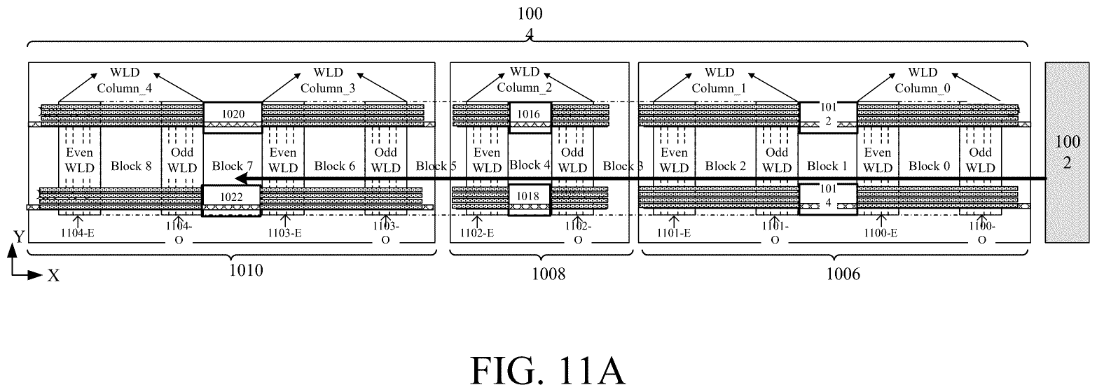

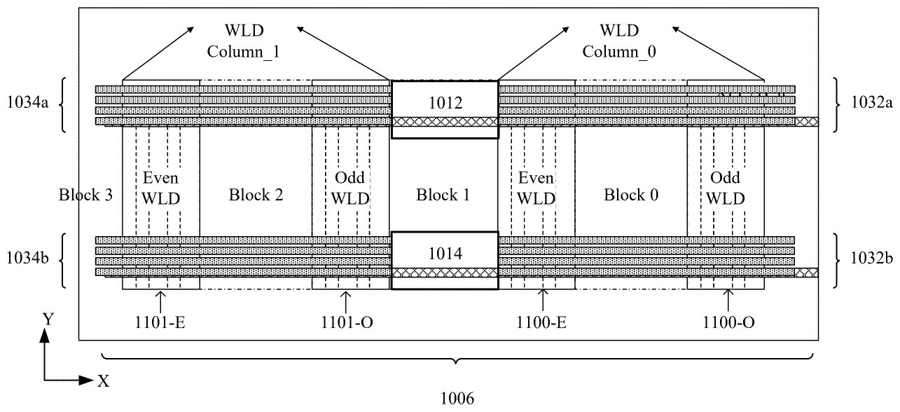

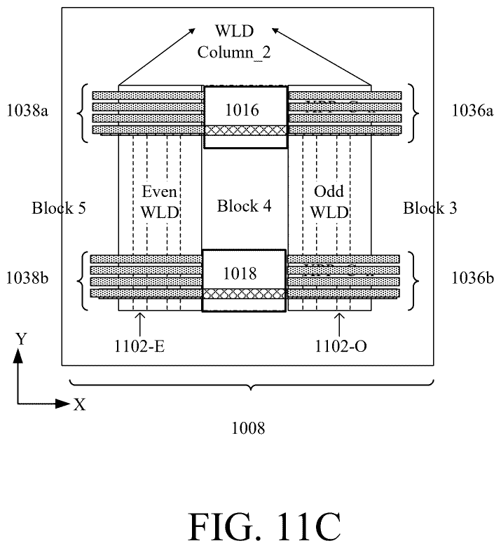

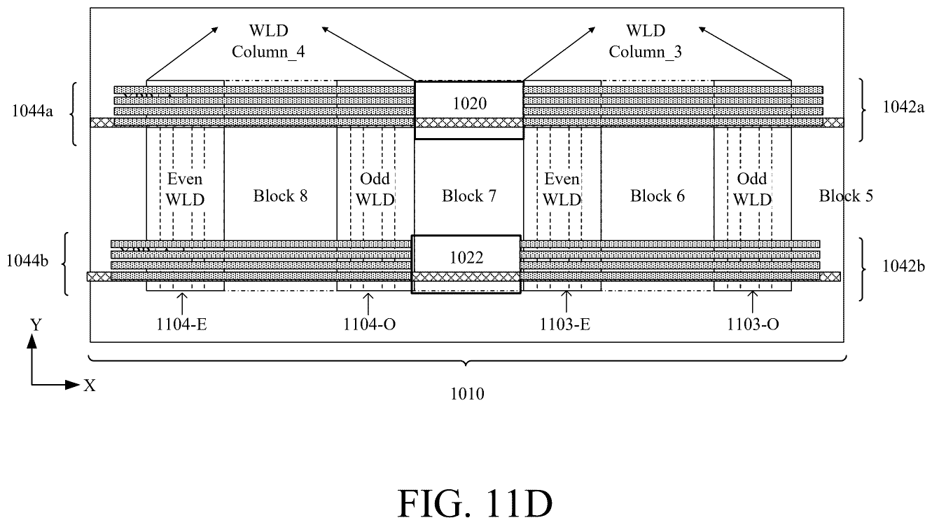

FIG. 11A is a partial schematic diagram of an example memory device according to an example of the present disclosure. The memory device includes a memory cell array and a peripheral circuit; and the memory cell array and the peripheral circuit are stacked in the vertical direction. The memory cell array includes a plurality of blocks, and the block includes a plurality of memory cells.

According to the present disclosure, the memory device is provided with a row decoder 1002 and a group array 1004. It is to be noted that FIG. 11A shows one row of the group array 1004 for example description. It is to be noted that the number of rows of groups shown in FIG. 11 is not used to limit the number of rows of blocks included in each of the groups in the present disclosure. The group array 1004 includes a first group 1006, a second group 1008, and a third group 1010. Each group includes at least one block. The implementation according to the present disclosure is not limited to having three groups, and various implementations may have more or less groups. Furthermore, the group in any implementation may have the same or different number of blocks.

Still referring to FIG. 11A, the first group 1006 may be coupled with word line drivers 1100-O, 1100-E, 1101-O, and 1101-E, where the word line drivers 1100-O and 1101-O are odd number word line drivers, and the word line drivers 1100-E and 1101-E are even number word line drivers. In some implementations, a drive circuit of the first group may include a first power supply circuit 1012 and a second power supply circuit 1014 coupled with the word line drivers; and the first power supply circuit 1012 and the second power supply circuit 1014 may be located between WLD Column_0 (including 1100-O and 1100-E) and WLD Column_1 (including 1101-O and 1101-E).

The second group 1008 may be coupled with WLD Column_2 (including an odd number word line driver 1102-O and an even number word line driver 1102-E). In some implementations, a drive circuit of the second group may include a first power supply circuit 1016 and a second power supply circuit 1018 coupled with the word line drivers; and the first power supply circuit 1016 and the second power supply circuit 1018 may be located between the odd number word line driver 1102-O and the even number word line driver 1102-E.

The third group 1010 may be coupled with word line drivers 1103-O, 1103-E, 1104-O, and 1104-E, where the word line drivers 1103-O and 1104-O are odd number word line drivers, and the word line drivers 1103-E and 1104-E are even number word line drivers. In some implementations, a drive circuit of the third group may include a first power supply circuit 1020 and a second power supply circuit 1022 coupled with the word line drivers; and the first power supply circuit 1020 and the second power supply circuit 1022 may be located between WLD Column_3 (including 1103-O and 1103-E) and WLD Column_4 (including 1104-O and 1104-E).

As shown in FIG. 11A, the first power supply circuits 1012, 1016, and 1020 overlap with the group in the vertical direction, and in some implementations, overlap with at least one block in the group. Likewise, the second power supply circuits 1014, 1018, and 1022 overlap with the group in the vertical direction, and in some implementations, overlap with at least one block in the group. In other words, projections of the first power supply circuit 1012 and the second power supply circuit 1014 in the drive circuit of the first group in the vertical direction may be partially overlapped with a projection of the at least one block in the first group 1006, and the word line drivers 1100-O, 1100-E, 1101-O, and 1101-E in the drive circuit of the first group may be located among various blocks in the first group 1006. Projections of the first power supply circuit 1016 and the second power supply circuit 1018 in the drive circuit of the second group may be partially overlapped with a projection of the at least one block in the second group 1008, and the word line drivers 1102-O and 1103-E in the drive circuit of the second group may be located among various blocks in the second group 1008. Projections of the first power supply circuit 1020 and the second power supply circuit 1022 in the drive circuit of the third group may be partially overlapped with a projection of the at least one block in the third group 1010, and the word line drivers 1103-O, 1103-E, 1104-O, and 1104-E in the drive circuit of the third group may be located among various blocks in the third group 1010.

In some examples, the drive circuit further includes: a drive circuit interconnection line configured to achieve the coupling between the first power supply circuit and the word line driver, and to achieve the coupling between the second power supply circuit and the word line driver, where an orthographic projection of the drive circuit interconnection line is located in the orthographic projection of the group, and the drive circuit interconnection line extends along the word-line direction.

FIG. 11B is an enlarged schematic diagram of an example first group 1006 according to an example of the present disclosure. Referring to FIG. 11B, the first group 1006 includes a first block (block 0), a second block (block 1), a third block (block 2), and a first portion of a fourth block (e.g., a first portion of a block 3). According to the present disclosure, drive circuit interconnection lines 1032a, 1032b, 1034a, and 1034b of the drive circuit of the first group may be respectively connected to the even number word line drivers and the odd number word line drivers, e.g., among the drive circuit interconnection lines XPPb<15:0>, XPPb<0,2,4,6,8,10,12,14> are connected to the even number word line drivers, and XPPb<1,3,5,7,9,11,13,15> are connected to the odd number word line drivers. The drive circuit interconnection lines 1032a, 1032b, 1034a, and 1034b extend along an X-axis direction within a boundary range of the first group 1006, in other words, the drive circuit interconnection lines 1032a, 1032b, 1034a, and 1034b do not extend beyond a boundary of the first group 1006 into other groups. The drive circuit interconnection lines 1032a and 1034a coupled with the first power supply circuit 1012 occupy a set of horizontal routing channels; and the drive circuit interconnection lines 1032b and 1034b coupled with the second power supply circuit 1014 occupy another set of horizontal routing channels. Herein, a horizontal direction is the X-axis direction.

FIG. 11C is an enlarged schematic diagram of an example second group 1008 according to an example of the present disclosure. Referring to FIG. 11C, the second group 1008 includes a second portion of the fourth block (e.g., a second portion of the block 3), a fifth block (block 4), and a first portion of a sixth block (e.g., a first portion of a block 5). According to the present disclosure, drive circuit interconnection lines 1036a, 1036b, 1038a, and 1038b of the drive circuit of the second group may be respectively connected to the even number word line driver and the odd number word line driver, e.g., among the drive circuit interconnection lines XPPc<15:0>, XPPc<0,2,4,6,8,10,12,14> are connected to the even number word line drivers, and XPPc<1,3,5,7,9,11,13,15> are connected to the odd number word line drivers. The drive circuit interconnection lines 1036a, 1036b, 1038a, and 1038b extend along the X-axis direction within a boundary range of the second group 1008. In other words, the drive circuit interconnection lines 1036a, 1036b, 1038a, and 1038b do not extend beyond a boundary of the second group 1008 into other groups. The drive circuit interconnection lines 1036a and 1038a coupled with the first power supply circuit 1016 occupy a set of horizontal routing channels; and the drive circuit interconnection lines 1036b and 1038b coupled with the second power supply circuit 1018 occupy another set of horizontal routing channels. Herein, a horizontal direction is the X-axis direction.

FIG. 11D is an enlarged schematic diagram of an example third group 1010 according to an example of the present disclosure. The third group 1010 includes a second portion of the sixth block (e.g., a second portion of the block 5), a seventh block (block 6), an eighth block (block 7), and a ninth block (block 8). According to the present disclosure, drive circuit interconnection lines 1042a, 1042b, 1044a, and 1044b of the drive circuit of the third group may be respectively connected to the even number word line driver and the odd number word line driver, e.g., among the drive circuit interconnection lines XPPa<15:0>, XPPa<0,2,4,6,8,10,12,14> are connected to the even number word line drivers, and XPPa<1,3,5,7,9,11,13,15> are connected to the odd number word line drivers. The drive circuit interconnection lines 1042a, 1042b, 1044a, and 1044b extend along the X-axis direction within a boundary range of the third group 1010, in other words, the drive circuit interconnection lines 1042a, 1042b, 1044a, and 1044b do not extend beyond a boundary of the third group 1010 into other groups. The drive circuit interconnection lines 1042a and 1044a coupled with the first power supply circuit 1020 occupy a set of horizontal routing channels; and the drive circuit interconnection lines 1042a and 1044a coupled with the second power supply circuit 1022 occupy another set of horizontal routing channels.

Referring to FIGS. 11B to 11D, the drive circuit interconnection lines 1032a and 1034a of the first group 1006, the drive circuit interconnection lines 1036a and 1038a of the second group 1008, and the drive circuit interconnection lines 1042a and 1044a of the third group 1010 occupy the same horizontal routing channels. That is, the drive circuit interconnection lines, coupled with the first power supply circuit, of the first, second, and third groups occupy the same horizontal routing channels, and are not connected with each other. The drive circuit interconnection lines 1032b and 1034b of the first group 1006, the drive circuit interconnection lines 1036b and 1038b of the second group 1008, and the drive circuit interconnection lines 1042b and 1044b of the third group 1010 occupy the same horizontal routing channels. That is, the drive circuit interconnection lines coupled with the second power supply circuit of the first, second, and third groups occupy the same horizontal routing channels, and are not connected with each other. That is, the drive circuit interconnection lines of each of the groups are located within orthographic projection ranges of the respective groups (referring to FIG. 11). Therefore, in the examples of the present disclosure, by integrating the routing channels occupied by the drive circuit interconnection lines of each group, the routing channels occupied by the drive circuit interconnection lines of each group may be shared, so as to reduce the number of the horizontal routing channels required by each group.

In some examples, the memory device includes a dynamic random access memory.

In some examples, the memory cell array includes a plurality of memory cells, and each memory cell includes one vertical transistor and one capacitor.

According to the above-mentioned examples of the present disclosure, the first power supply circuit, the second power supply circuit, and the drive circuit interconnection lines coupled with the first power supply circuit and the second power supply circuit are re-arranged in the present disclosure, such that the first power supply circuit, the second power supply circuit, and the drive circuit interconnection lines coupled with the first power supply circuit and the second power supply circuit may be arranged in the space available in the group, thereby reducing the area occupied by the drive circuit, and effectively reducing a size of the memory device.

Examples of the present disclosure further provide a memory system. The memory system includes one or more memory devices described in any one of the above-mentioned examples, and a memory controller coupled to the memory device and configured to control the memory device.

Herein, specific structures and compositions with respect to the memory system may be referred to related structures and compositions of the memory system 102 in FIG. 1. For simplicity, details are not described herein again.

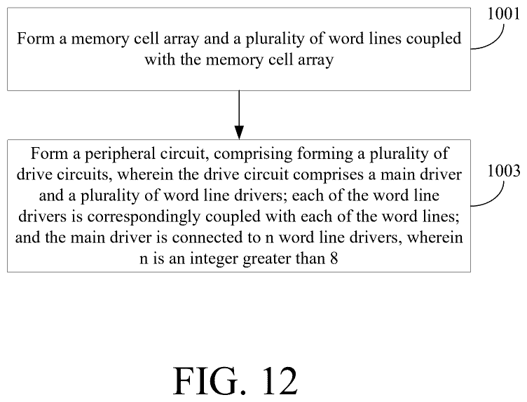

Based on the above-mentioned memory device, examples of the present disclosure further provide a manufacturing method of a memory device. As shown in FIG. 12, the method includes the following operations. Operation 1001 may include forming a memory cell array and a plurality of word lines coupled with the memory cell array; and operation 1003 may include forming a peripheral circuit, including forming a plurality of drive circuits, where the drive circuit includes a main driver and a plurality of word line drivers; each of the word line drivers is correspondingly coupled with each of the word lines; and the main driver is connected to n word line drivers, where n is an integer greater than 8.

In some examples, forming the plurality of drive circuits includes forming a pre-charge circuit and an output circuit, where a transistor size of a transistor in the output circuit is greater than a transistor size of a transistor in the pre-charge circuit.

In some examples, a ratio of a transistor size of a transistor in the output circuit to a transistor size of a transistor in the pre-charge circuit ranges from 1.5 to 2.

In some examples, the main driver is connected to 16 word line drivers.

In some examples, forming the peripheral circuit further includes: forming a row decoder, where the row decoder is coupled to the drive circuit and configured to: decode 9th-bit to 5th-bit row addresses in a row address signal of m bits to generate a main drive signal, and decode the row addresses of the lowest 4 bits in the row address signal of m bits to generate a word line drive signal, where m is an integer greater than 9; and the word line driver is configured to: drive a target word line based on the main drive signal and the word line drive signal.

In some examples, forming the memory cell array includes: forming the memory cell array including a plurality of banks, where each of the banks includes a plurality of groups, and each of the groups includes at least one block; and an orthographic projection of the drive circuit is located in an orthographic projection of the group.

In some examples, the blocks in the group are arranged in an array along a word-line direction and a bit-line direction; and forming the plurality of drive circuits includes: forming the plurality of word line drivers, where an orthographic projection of the word line driver is located between orthographic projections of the blocks adjacent to each other along the word-line direction.

In some examples, the plurality of banks are arranged in an array along a word-line direction and a bit-line direction; and forming the row decoder includes: forming the row decoder whose orthographic projection is located between orthographic projections of the banks adjacent to each other along the bit-line direction.

In some examples, forming the peripheral circuit further includes forming a first power supply circuit, where the first power supply circuit is configured to supply a charge voltage to the word line driver, where an orthographic projection of the first power supply circuit is located in the orthographic projection of the block.

In some examples, forming the peripheral circuit further includes forming a second power supply circuit, where the second power supply circuit is configured to supply a discharge voltage to the word line driver, where an orthographic projection of the second power supply circuit is located in the orthographic projection of the block.

In some examples, forming the peripheral circuit further includes: forming a drive circuit interconnection line, where the drive circuit interconnection line is configured to achieve the coupling between the first power supply circuit and the word line driver, and to achieve the coupling between the second power supply circuit and the word line driver, where an orthographic projection of the drive circuit interconnection line is located in the orthographic projection of the group, and the drive circuit interconnection line extends along the word-line direction.

In some examples, one of the word line drivers on two sides of the first one among the plurality of blocks is coupled to an even number word line, and the other one is coupled to an odd number word line.

In some examples, forming the memory cell array includes forming a plurality of memory cells, where each memory cell includes one vertical transistor and one capacitor.

In some examples, forming the memory cell array includes forming the memory cell array on a first substrate; forming the peripheral circuit includes: forming the peripheral circuit on a second substrate; and the method further includes: bonding the memory cell array and the peripheral circuit.

Examples of the present disclosure provide a memory device and a manufacturing method thereof, and a memory system. The memory device includes: a memory cell array; a plurality of word lines coupled with the memory cell array; and a peripheral circuit coupled with the memory cell array through the plurality of word lines and including a drive circuit, where the drive circuit includes a main driver and a plurality of word line drivers; each of the word line drivers is correspondingly coupled with each of the word lines; and the main driver is connected to n word line drivers, where n is an integer greater than 8. In the examples of the present disclosure, each main driver is connected to more than 8 word line drivers, such that one main driver may drive more than 8 word lines (local word lines), thereby greatly improving an integration level of the memory device.

It is to be understood that “one example” and “an example” mentioned in the whole specification mean that particular features, structures or characteristics related to the example is included in at least one example of the present disclosure. Therefore, “in one example” or “in an example” appearing at any place of the whole specification does not always refer to the same example. In addition, these particular features, structures or characteristics may be combined in one or more examples in any proper manner. It is to be understood that, in various examples of the present disclosure, the sequence number of each process does not mean the sequence of execution. The execution sequence of each process should be determined by its functions and internal logic, which should not constitute any limitation on the implementation process of the examples of the present disclosure. The above sequence numbers of the examples of the present disclosure are only for description, and do not represent goodness and badness of the examples.

The above descriptions are merely preferred implementations of the present disclosure, and not intended to limit the patent scope of the present disclosure. Equivalent structure transformation made within using the contents of the specification and the drawings of the present disclosure under the inventive concept of the present disclosure, or direct/indirect application to other related technical fields are both encompassed within the patent protection scope of the present disclosure.

What is claimed is:

1. A memory device, comprising:
a memory cell array;
a plurality of word lines coupled with the memory cell array; and
a peripheral circuit coupled with the memory cell array through the plurality of word lines and comprising a drive circuit,
wherein the drive circuit comprises a main driver and a plurality of word line drivers, each of the word line drivers is correspondingly coupled with each of the word lines, and the main driver is connected to n word line drivers, wherein n is an integer greater than 8.

2. The memory device of claim 1, wherein the main driver comprises a pre-charge circuit and an output circuit, a transistor size of a transistor in the output circuit is greater than a transistor size of a transistor in the pre-charge circuit.

3. The memory device of claim 2, wherein a ratio of a transistor size of a transistor in the output circuit to a transistor size of a transistor in the pre-charge circuit ranges from 1.5 to 2.

4. The memory device of claim 1, wherein the main driver is connected to 16 word line drivers.

5. The memory device of claim 1, wherein the peripheral circuit further comprises:
a row decoder coupled to the drive circuit and configured to decode 9th-bit to 5th-bit row addresses in a row address signal of m bits to generate a main drive signal, and decode the row addresses of the lowest 4 bits in the row address signal of m bits to generate a word line drive signal, wherein m is an integer greater than 9; and
the drive circuit is configured to drive a target word line based on the main drive signal and the word line drive signal.

6. The memory device of claim 5, wherein
the memory cell array comprises a plurality of banks, each of the banks comprises a plurality of groups, and each of the groups comprises at least one block; and
an orthographic projection of the drive circuit is located in an orthographic projection of the group.

7. The memory device of claim 6, wherein
the blocks in each of the groups are arranged in an array along a word-line direction and a bit-line direction; and
an orthographic projection of the word line driver is located between orthographic projections of the blocks adjacent to each other along the word-line direction.

8. The memory device of claim 6, wherein
the plurality of banks are arranged in an array along a word-line direction and a bit-line direction; and
an orthographic projection of the row decoder is located between orthographic projections of the banks adjacent to each other along the bit-line direction.

9. The memory device of claim 7, wherein
the drive circuit further comprises a first power supply circuit configured to supply a charge voltage to the word line driver; and
an orthographic projection of the first power supply circuit is located in the orthographic projection of the block.

10. The memory device of claim 9, wherein
the drive circuit further comprises a second power supply circuit configured to supply a discharge voltage to the word line driver; and
an orthographic projection of the second power supply circuit is located in the orthographic projection of the block.

11. The memory device of claim 10,
wherein the drive circuit further comprises a drive circuit interconnection line configured to achieve the coupling between the first power supply circuit and the word line driver, and to achieve the coupling between the second power supply circuit and the word line driver; and
an orthographic projection of the drive circuit interconnection line is located in the orthographic projection of the group, and the drive circuit interconnection line extends along the word-line direction.

12. The memory device of claim 7, wherein one of the word line drivers on two sides of a first one among the plurality of blocks is coupled to an even number word line, and the other one is coupled to an odd number word line.

13. The memory device of claim 1, wherein the memory cell array comprises a plurality of memory cells, and each memory cell comprises one vertical transistor and one capacitor.

14. The memory device of claim 1, wherein the memory cell array and the peripheral circuit are formed on different substrates, and the peripheral circuit and the memory cell array are stacked in a vertical direction.

15. A memory system, comprising:
a memory device, comprising:
a memory cell array;
a plurality of word lines coupled with the memory cell array; and
a peripheral circuit coupled with the memory cell array through the plurality of word lines and comprising a drive circuit, wherein
the drive circuit comprises a main driver and a plurality of word line drivers, each of the word line drivers is correspondingly coupled with each of the word lines, and the main driver is connected to n word line drivers, wherein n is an integer greater than 8; and
a memory controller coupled to the memory device and configured to control the memory device.

16. A method of manufacturing a memory device, comprising:
forming a memory cell array and a plurality of word lines coupled with the memory cell array; and
forming a peripheral circuit, comprising:
forming a plurality of drive circuits, wherein the drive circuit comprises a main driver and a plurality of word line drivers, each of the word line drivers is correspondingly coupled with each of the word lines, and the main driver is connected to n word line drivers, wherein n is an integer greater than 8.

17. The method of claim 16, wherein the forming the plurality of drive circuits comprises:
forming a pre-charge circuit and an output circuit, wherein a transistor size of a transistor in the output circuit is greater than a transistor size of a transistor in the pre-charge circuit.

18. The method of claim 17, wherein a ratio of a transistor size of a transistor in the output circuit to a transistor size of a transistor in the pre-charge circuit ranges from 1.5 to 2.

19. The method of claim 16, wherein the main driver is connected to 16 word line drivers.

20. The method of claim 16, wherein the forming the peripheral circuit further comprises:
forming a row decoder, wherein the row decoder is coupled to the drive circuit and configured to: decode 9th-bit to 5th-bit row addresses in a row address signal of m bits to generate a main drive signal, and decode the row addresses of the lowest 4 bits in the row address signal of m bits to generate a word line drive signal, wherein m is an integer greater than 9; and
the word line driver is configured to: drive a target word line based on the main drive signal and the word line drive signal.
